(19) United States
(12) Patent Application Publication
(10) Pub. No.: US 2007/0133174 A1
(43) Pub. Date: Jun. 14, 2007

(54) Information processor with a radiator that includes a heat pipe

(75) Inventors: Masashi Mikami, Ome-shi (JP); Heiwa Matsuoka, Tachikawa-shi (JP); Yusuke Sugiura, Ome-shi (JP)

Correspondence Address: PILLSBURY WINTHROP SHAW PITTMAN, LLP, P.O. BOX 10500, MCLEAN, VA, 22102, US

(73) Assignee: KABUSHIKA KAISHA TOSHIBA, Tokyo (JP)

(21) Appl. No.: 11/606,000

(22) Filed: Nov. 30, 2006

(30) Foreign Application Priority Data
Nov. 30, 2005 (JP) 2005-345903

(51) Int. Cl. G06F 1/20; H05K 7/20

(52) U.S. Cl. 361/700; 361/687

(57) ABSTRACT

According to one embodiment, an information processor includes a semiconductor device, a heat pipe and an insulated magnetic member. The semiconductor device is provided on a substrate, and emits electromagnetic radiation and heat during an operation thereof. The heat pipe includes a heat-receiving end and a heat-radiating end. The heat-receiving end is fixed to the semiconductor device to transmit the heat emitted from the semiconductor device. The heat-radiating end is separate from the semiconductor device. The magnetic member is mounted on the outer peripheral surface of the heat pipe between the heat-receiving end and the heat-radiating end.

### CROSS-REFERENCE TO RELATED APPLICATIONS

This application is based upon and claims the benefit of priority from Japanese Patent Application No. 2005-345903, filed Nov. 30, 2005, the entire contents of which are incorporated herein by reference.

### BACKGROUND

1. Field

An embodiment of the present invention relates to an information processor with a radiator that includes a heat pipe mounted on a semiconductor device as a heat generator.

2. Description of the Related Art

Semiconductor devices for performing computational operations are mounted on the substrate installed in the main unit of an information processor. When a semiconductor device operates, a current flows therethrough, and hence electromagnetic radiation is generated and circuit resistance occurs therein. As a result, the semiconductor device generates heat. The higher the density of circuits in the semiconductor device, and the higher the operation speed, the greater the generated electromagnetic radiation and heat.

Jpn. Pat. Apple. KOKAI Publication No. 2004-103673, for example, discloses an electromagnetic-wave-absorbing radiator sheet provided for the electronic components of an electronic device for suppressing emitting of electromagnetic radiation without interrupting heat release. This sheet comprises a sheet body containing a thermal conductive material, and a thin layer stacked on the sheet body and containing a magnetic material. In the publication, the sheet is held between the surface of a heat-generating electronic component, such as a CPU, and radiator fins.

Further, Jpn. Pat. Apple. KOKAI Publication No. 2005-79325 discloses a technique for eliminating the heat generated by a CPU, using a heat pipe. The heat-receiving end of the heat pipe is fixed to a heat-receiving plate thermally coupled to the CPU. The heat-receiving plate is formed of a metal of excellent thermal conductivity. A cooling fan is formed integral with the heat-receiving plate positioned away from the CPU. The heat-radiating end of the heat pipe is thermally coupled to the sidewall of the case of the cooling fan.

However, if the heat-radiating end of the heat pipe is extended to the outlet of the cooling fan, this means that the heat pipe is extended from the semiconductor device over a long distance. Since the heat pipe is generally formed of a copper alloy having excellent thermal conductivity, it may serve as an antenna. In this case, the heat pipe picks up electromagnetic radiation generated as noise by the semiconductor device, and outputs it to the outside of the information processor.

In particular, if the frequency of the noise generated by the semiconductor device is the resonant frequency of the heat pipe because of the length of the heat pipe, the noise is amplified to a level that influences circuits of peripheral devices. To prevent electromagnetic radiation from being transmitted to the outside, the heat-radiating end of the heat pipe is often grounded.

There are two methods for grounding the heat-radiating end of the heat pipe. In one method, the heat-radiating end or middle portion of the heat pipe is pressed against a gasket or spring connected to the ground terminal of the substrate. In the other method, the heat-radiating end of the heat pipe is directly screwed to the portion of the substrate on which the ground terminal is provided. Alternatively, it is possible to provide a lead between the heat-radiating end and ground.

However, in the case of connecting the heat pipe to the ground terminal of the substrate via the gasket or spring, it is necessary to bring the heat pipe into tight contact with the ground terminal in order to secure sufficient contact area. In this case, a force is exerted on the heat-radiating end of the heat pipe by the gasket and/or spring, raising the heat-radiating end from the substrate. If the gasket or spring are strongly pressed so as not to raise the heat-radiating end, they are compressed, thereby raising the part of the heat-receiving end away from the heat-radiating end, since the part of the heat pipe near the heat-radiating end acts as a fulcrum. In contrast, if insufficient pressure is applied to the gasket and spring, the gasket and spring may not sufficiently keep the heat-receiving end in contact with the semiconductor device.

Further, when the heat-radiating end of the heat pipe is connected to the ground terminal of the substrate using a screw, it is necessary to reliably tighten the screw so that the screw will not be loosened by, for example, vibration. If the contact surface of the heat-radiating end is not ideally angled, part of the heat-receiving end may be raised from the semiconductor device when the screw is tightened.

The temperature of the heat-radiating end of the heat pipe increases more quickly than the ambient temperature. When the semiconductor device generates heat and the entire heat pipe is expanded, if the heat-receiving end is firmly fixed to secure heat transmission efficiency at the heat-receiving end, the contact surface of the heat-radiating end may easily be displaced. In other words, in the method of directly coupling the heat-radiating end to the substrate, it is difficult to secure sufficient contact area. Furthermore, if the heat-radiating end is firmly held to be reliably grounded, the heat-receiving end may be raised from the semiconductor device, thereby reducing the heat transmission efficiency. In the method of directly grounding the heat-radiating end using a lead, a stabilized grounding state can be obtained regardless of the expansion of the heat pipe. This method, however, requires a terminal for connecting the lead, and makes assembly complex.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary partly broken perspective view illustrating an information processor according to an embodiment of the invention;

FIG. 2 is an exemplary exploded perspective view obtained when the semiconductor device, radiator and cooling fan of the information processor of FIG. 1 are viewed from below; and

FIG. 3 is a exemplary plan view obtained when part of the information processor of FIG. 2 is viewed from below.

### DETAILED DESCRIPTION

Various embodiments according to the invention will be described hereinafter with reference to the accompanying drawings. In general, according to one embodiment of the invention, there is provided an information processor comprises a semiconductor device, a heat pipe and an insulated magnetic member. The semiconductor device is provided on a substrate and emits electromagnetic radiation and heat during an operation thereof. The heat pipe has its heat-receiving end fixed to the semiconductor device to transmit the heat emitted from the semiconductor device. The heat pipe has its heat-radiating end separate from the semiconductor device. The insulated magnetic member is attached to the outer peripheral surface of the heat pipe between the heat-receiving end and the heat-radiating end.

The objects and advantages of the invention may be apparent from the description which follows, or may be learned by the practice of the invention.

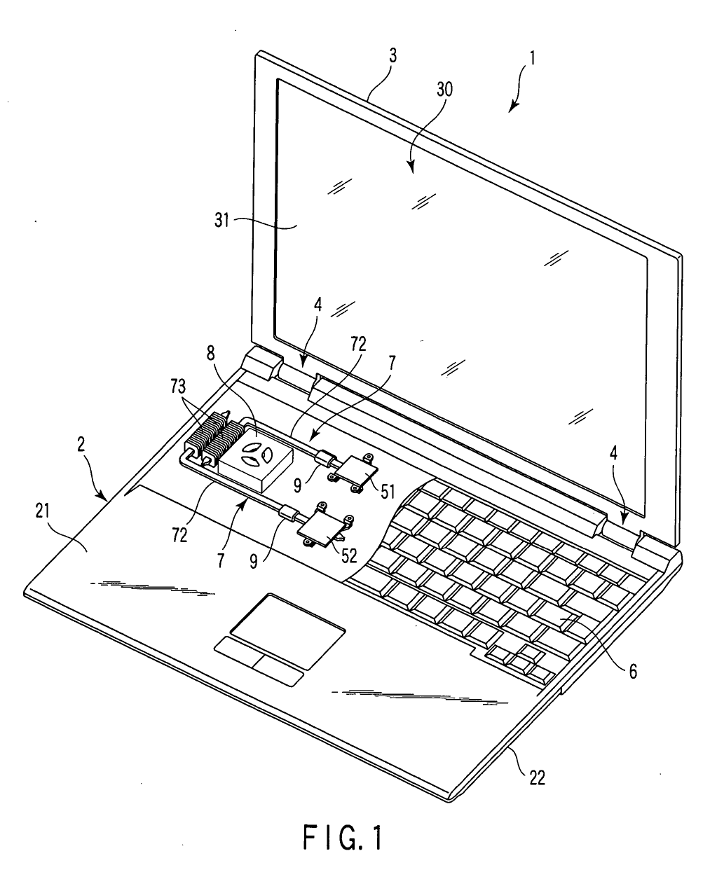

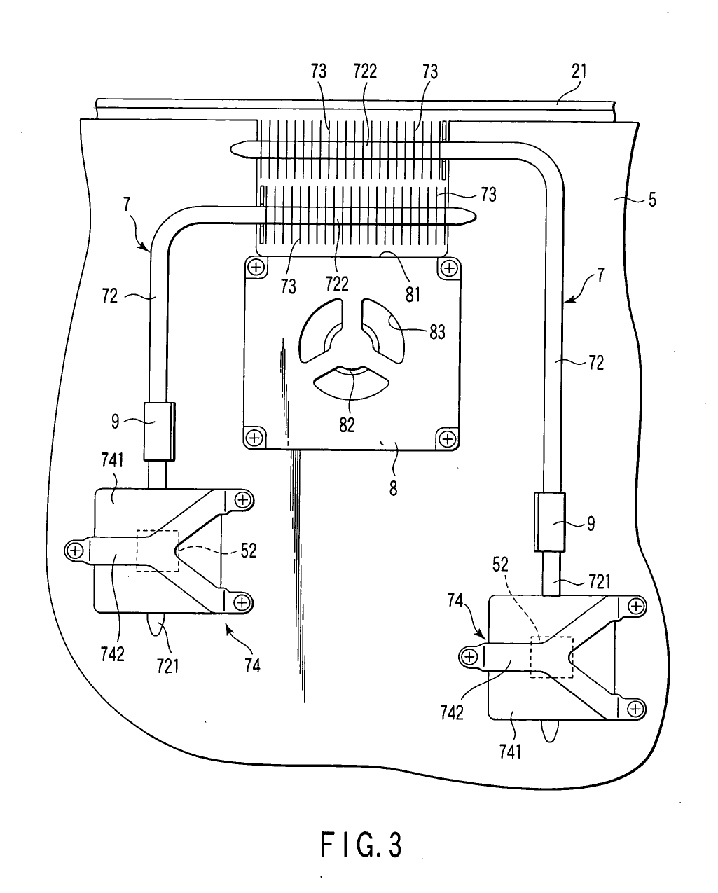

Referring to FIGS. 1 to 3, an information processor 1 according to an embodiment of the invention will be described. As shown in FIG. 1, the information processor 1 comprises a main unit 2 and display panel 3. The main unit 2 and display panel 3 are coupled to each other by hinges 4 at the rear side of the apparatus, that in view of the user side.

The main unit 2 has a case 20 for outer shell and contains therein a substrate 5, large-capacity memory device, and communication module, etc. The case 20 includes an upper case component 21 and lower case component 22, which are located above and below, respectively, when the apparatus is placed on, for example, a desk. A keyboard 6 as input means is mounted on the upper case component 21.

The display panel 3 can pivot about the hinges 4 between a closed position in which it is placed on the main unit 2, and an open position in which it stands as shown in FIG. 1. The display panel 3 includes a display unit 30 with a display surface 31 that faces a user when the panel 3 is in the open position. The hinges 4 have a rotational resistance that enables the display panel 3 to be fixed at an arbitrary angle to the main unit 1.

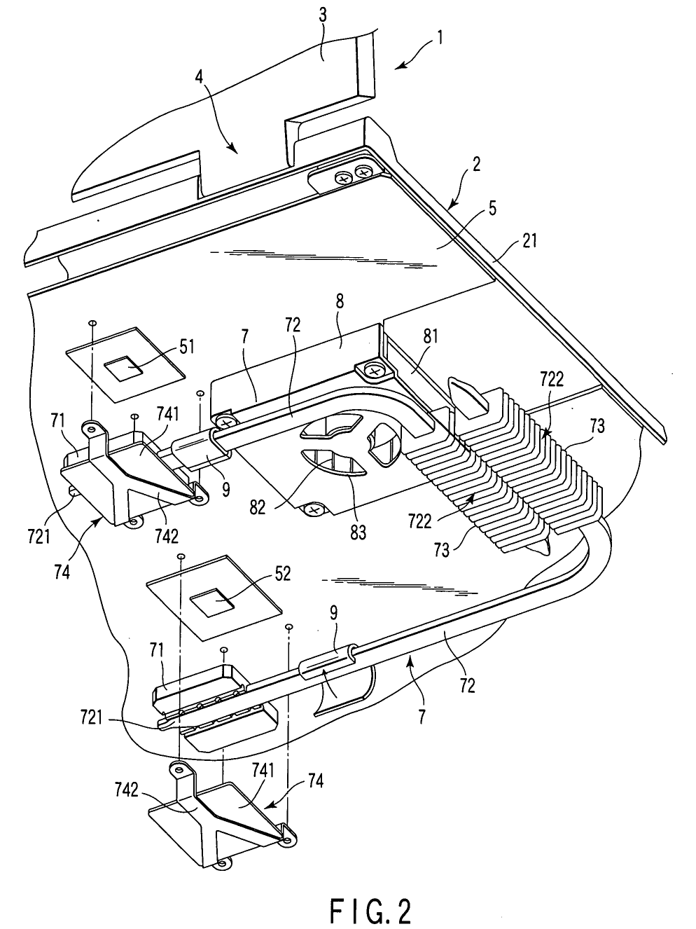

As shown in FIG. 2, semiconductor devices 51 and 52 are mounted on the lower surface of the substrate 5 contained in the main unit 2. The semiconductor devices 51 and 52 include a central processing unit (CPU), micro processing unit (MPU) and graphics processing unit (GPU), etc. The semiconductor devices 51 and 52 generate heat because of the resistances of the internal circuits, and also generate electromagnetic radiation as high-frequency noise according to the operation speed. Respective radiators 7 are provided for the semiconductor devices 51 and 52. The main unit 2 also contains a cooling fan 8 fixed on the substrate 5. In FIG. 1, the keyboard 6, upper case component 21 and substrate 5 are partially cut to show the semiconductor devices 51 and 52, radiators 7 and cooling fan 8 provided on the lower surface of the substrate 5.

Each radiator 7 comprises a heat receptor 71, heat pipe 72, radiator fins 73 and fixing member 74. The heat receptor 71 has a flat surface to be fit with the corresponding semiconductor device 51 (52) that is exposed at the lower surface of the substrate 5. To secure sufficient heat transmission area, it may be filled the space between the semiconductor device 51 (52) and the heat receptor 71 with paste or gel of a high thermal conductivity, or heat transfer sheet having elasticity.

The heat pipe 72 includes a tubular container with opposite closed ends, a wick provided on the inner wall of the container along the entire length of the container, and an operating fluid sealed in the container. The heat pipe 72 has heat-receiving ends 721 at which the operating fluid is exposed to high temperature and evaporated, and heat-radiating ends 722 at which the evaporated operating fluid is exposed to low temperature and condensed.

The container is exemplary formed of copper or an aluminum alloy that has excellent thermal conductivity. The wick is used to circulate the liquidized operating fluid from the condensing section of each heat-radiating end 722 to the evaporating section of the corresponding heat-receiving end 721, utilizing capillary phenomenon. The wick may be directly formed on the inner surface of the container, or be formed of a mesh member and inserted in the container. The operating fluid is evaporated by the heat received and condensed by heat radiation. In general, pure water or an ammonia solution, etc. is used as the operating fluid.

As shown in FIG. 2, each heat-receiving end 721 of the heat pipe 72 is fixed to the heat receptor 71 by clamping, and brazed by, for example, silver brazing alloy to enhance the heat transmittance. The heat-radiating ends 722 are located on the substrate 5 away from the semiconductor devices 51 and 52. In the embodiment, the heat-radiating ends 722 are located downstream of the air outlet 81 of the cooling fan 8 across the air stream exhausted from the air outlet 81.

A number of radiator fins 73 are incorporated in each heat-radiating end 722 at regular intervals along the stream exhausted through the air outlet 81 of the cooling fan 8. The radiator fins 73 are press-fitted on the heat pipe 72. In the embodiment, the heat-radiating end 722 of the heat pipe 72 of the radiator 7 mounted on the semiconductor device 51 is located parallel to the heat-radiating end 722 of the heat pipe 72 of the radiator 7 mounted on the semiconductor device 52, downstream of the cooling fan 8.

Each fixing member 74 is formed of a plate 741 and leg portion 742 for pressing the corresponding heat receptor 71 with the heat-receiving end 721 against the corresponding semiconductor device 51 (52). The plates 741 are held by the respective leg portions 742 to uniformly press the respective heat receptors 71 against the semiconductor devices 51 and 52.

The cooling fan 8 is located outside the semiconductor devices 51 and 52 on the substrate 5 in the main unit 2, and the air outlet 81 outwardly opens. The cooling fan 8 introduces the ambient air through an air inlet 83 that opens along the axis of rotation of a rotor 82, and exhausts it centrifugally. An ambient-air inlet may be provided in the portion of the lower case component 22 corresponding to the air inlet 83. Further, if the air in the case 20 is introduced as the ambient air into the cooling fan 8, even the heated air stagnating in the case 20 can be positively exhausted.

Further, as shown in FIG. 2, insulated magnetic sheets 9 are wound on the respective heat pipes 72 between the respective heat-receiving ends 721 and heat-radiating ends 722. The insulated magnetic sheets 9 are flexible and contain a magnetic substance. Since the sheets 9 each have one surface with an adhesive sheet, they can be easily attached to the outer peripheral surfaces of the respective heat pipes 72.

The electromagnetic radiation emitted as noise from the semiconductor devices 51 and 52 causes current to occur at the heat-receiving ends 721 by electromagnetic induction. If the frequency of the current is identical to an integral multiple of the intrinsic impedance of the heat pipes, the entire heat pipes 72 serve as amplifiers and resonate with the noise, thereby generating strong electromagnetic radiation to the outside.

In the information processor 1 of the embodiment, the insulated magnetic sheets 9 are wound around the heat pipes 72 near the heat-receiving ends 721 as current generation sources. The magnetic sheets 9 generate magnetic fields that offset the magnetic fields generated by the current flowing through the heat pipes 72. As a result, the current flowing through the heat pipes 72 is attenuated, and hence the electromagnetic radiation generated to the outside is suppressed. Namely, the magnetic sheets 9 wound around the heat pipes 72 vary the intrinsic impedance of the heat pipes 72. It would further be better to adjust the number of windings or winding width of the magnetic sheets 9, so that the intrinsic impedance of the heat pipes 72 does not make the current flowing therethrough resonate with the electromagnetic radiation emitted as noise from the semiconductor devices 51 and 52.

It is sufficient if the magnetic sheets 9 are magnetic members for suppressing the current flowing through the heat pipes 72. For instance, such a two-dividable core as attached to a communication cable may be attached to each heat pipe.

By attaching the above-described radiators to the semiconductor devices, heat radiation is accelerated, and the radiation of electromagnetic radiation is suppressed. Even if a radiator with a long heat pipe having a heat-radiating end thereof located on the outer surface of the case is mounted on a semiconductor device, which arranged at middle section of substrate, it is prevented from amplifying the noise emitted from the semiconductor device. Accordingly, in the information processor of the embodiment, various layouts can be realized on the substrate.

In the information processor of the embodiment, the heat-receiving ends of the heat pipes are fixed without degrading the efficiency of transmission of heat from the semiconductor devices to the heat-receiving ends, and the magnetic sheets can suppress the transmission of the electromagnetic radiation emitted as noise from the semiconductor devices that are operating.

The invention is not limited to the foregoing embodiment but various changes and modifications of its components may be made without departing from the scope of the present invention. Also, the components disclosed in the embodiment may be assembled in any combination for embodying the present invention. For example, some of the components may be omitted from all the components disclosed in the embodiment. Further, components in different embodiments may be appropriately combined.

What is claimed is:

1. An information processor comprising:
a semiconductor device provided on a substrate, the semiconductor device emitting electromagnetic radiation and heat during an operation thereof;
a heat pipe including a heat-receiving end and a heat-radiating end, said heat-receiving end being fixed to the semiconductor device to transmit the heat emitted from the semiconductor device, said heat-radiating end being separate from the semiconductor device; and
an insulated magnetic member attached to an outer peripheral surface of the heat pipe between the heat-receiving end and the heat-radiating end.

2. The information processor according to claim 1, wherein the magnetic member is a flexible magnetic sheet containing a magnetic substance.

3. The information processor according to claim 1, wherein the magnetic member is attached to the outer peripheral surface of the heat pipe near the heat-receiving end.

4. The information processor according to claim 1, further comprising:
a case which contains the substrate; and
a cooling fan contained in the case outside the semiconductor device,
and wherein the heat-radiating end of the heat pipe is located downstream of an air outlet of the cooling fan across an air stream discharged from the air outlet, the heat-radiating end including fins.

5. The information processor according to claim 4, wherein said fins are incorporated in each heat-radiated end at constant intervals along the stream exhausted from the air outlet of the cooling fan.

6. The information processor according to claim 4, wherein said cooling fan has a rotor which intakes an ambient air in the direction along the axis of rotation of the rotor, and exhausts said ambient air centrifugally.

7. The information processor according to claim 1, wherein said heat-receiving end has a heat-receiving member fastened by a fixing member to fit the semiconductor device.

8. The information processor according to claim 7, wherein said fixing member has a plate and a leg portion, said leg portion is fixed to the substrate to uniformly press the heat-receiving member against the semiconductor device.
